(19) United States
(12) Patent Application Publication
(10) Pub. No.: US 2025/0344551 A1
(43) Pub. Date: Nov. 6, 2025

(54) SOLAR CONTROL INTERLAYERS

(71) Applicant: DelStar Technologies, Inc., Alpharetta, GA (US)

(72) Inventors: Alexander James Kidwell, Maple Grove, MN (US); Thomas C. Niziolek, Feeding Hills, MA (US)

(21) Appl. No.: 19/194,195

(22) Filed: Apr. 30, 2025

Related U.S. Application Data
(60) Provisional application No. 63/642,034, filed on May 3, 2024.

(51) Int. Cl. H10F 77/42; H10F 77/45; H10K 30/50

(52) U.S. Cl. CPC H10F 77/488; H10F 77/45; H10K 30/50

(57) ABSTRACT

A functional interlayer for incorporation into laminated structures is provided. The functional interlayer may provide solar control properties to the laminated structure. The laminated structure may be part of a window unit. An interlayer comprises a thermoplastic polyurethane (TPU) layer comprising luminescent solar concentrators and an optical layer in contact with the TPU layer. The optical layer comprises one or more materials that reflect light back into the TPU layer. This allows the luminescent solar concentrators to harvest more energy from the same light rays, which increases the overall energy capture of the LSCs without compromising other functional properties, such as the visible light transmission (VLT), of the interlayer.

### CROSS-REFERENCE TO RELATED APPLICATIONS

This application claims the benefit of U.S. Provisional Application Ser. No. 63/642,034, filed May 3, 2024, the complete disclosure of which is incorporated herein by reference for all purposes.

### TECHNICAL FIELD

This description generally relates to interlayers having functional properties such as solar control properties and various structures including laminates, such as window units, with solar control interlayers.

### BACKGROUND

Solar control films or interlayers are used in windows for vehicles and dwellings to improve energy efficiency. In residential or commercial buildings, these solar control interlayers help control the heat gain through the window from sunlight. This helps reduce the load on heating, ventilation, and cooling systems, which improves energy efficiency and reduces utility costs. In automotive or other vehicles, fuel efficiency is improved by reducing the heat gain though windows and sunlight. Solar control interlayers remove energy from sunlight while allowing visible light to pass through. Some solar control interlayers remove energy from the infrared and/or near infrared range.

Laminated Glazing Units (LGUs) are laminated assemblies that include one or more interlayers interposed between transparent rigid plies. The rigid plies can be glass or any other well-known substitute such as polycarbonates, acrylic resins, polyesters, and rigid transparent polyurethanes. The interlayer, which bonds adjacent rigid plies together to form a unified laminated assembly, may be a thermoplastic material such as thermoplastic polyurethane (TPU), polyvinyl formal, polyvinyl butyral, polyvinyl iso-butyral, silicone or ethylene vinyl acetate (EVA).

Interlayers used in solar control laminates must have good adhesion to the rigid outer panes of the window. In addition, the interlayer must have optical clarity, durability, and suitable thermal and mechanical properties. The interlayers should have structural strength and load bearing capability in the event the rigid outer panes are broken due to crime, natural disaster, weather, etc.

Certain solar control interlayers comprise luminescent solar concentrators (LSCs), such as colloidal semiconductor nanocrystals (also called quantum dots) or organic photovoltaic (OPV) cells. The LSCs remove energy from sunlight while allowing visible light to pass through the window. The total quantity of LSCs within the interlayer is typically referred to as quantum dot (QD) loading. There is a positive correlation between the QD loading and the energy capture, i.e., the higher the QD loading, the more energy is captured by the interlayer. On the other hand, there is generally a negative correlation between the QD loading and the visible light transmission (VLT), i.e., the higher the QD loading, the less amount of visible light is passed through the interlayer.

It would be desirable to improve the QD loading of solar control interlayers without substantially comprising other properties of the interlayer, such as the VLT.

### SUMMARY

Interlayers having functional properties such as solar control properties and various structures including laminates with solar control interlayers are provided herein The laminated structures may be part of a window unit for a vehicle or building, or other structures, such as image sensors, electronic display screens for computers and mobile devices, food packaging, optical disk devices, appliances and the like.

In accordance with one aspect, an interlayer comprises a polymer layer comprising a plurality of luminescent solar concentrators and an optical layer in contact with the polymer layer. The optical layer comprises one or more materials or components that reflect light back into the polymer layer. This allows the luminescent solar concentrators to harvest more energy from the same light rays, which increases the overall energy capture of the LSCs without compromising other properties or functions of the interlayer.

The optical layer may comprise one or more materials that reflect ultraviolet (UV) light, infrared (IR) light, visible light, microwaves, radio waves or other wavelengths. In an exemplary embodiment, the materials reflect ultraviolet (UV) light and/or infrared (IR) light without substantially blocking or reflecting visible light.

In various embodiments, the polymer layer comprises one or more materials that provide good adhesion to the optical layer and/or other sheets in a laminate. In an exemplary embodiment, the polymer layer comprises a substantially transparent thermoplastic polyurethane (TPU) layer. The TPU layer may be formed by extrusion and suitable for use in a laminate, such as for a window unit. The TPU will preferably comprise a material that provides sufficient transparency to visible light and exhibits suitable adhesion to glass, polycarbonate, acrylic, cellulose acetate butyrate, or other surfaces which the layer may contact.

In various embodiments, the optical layer comprises a substantially transparent material that provides good adhesion to the TPU layer and/or other sheets in a laminate. In an exemplary embodiment, the optical layer comprises a substantially transparent TPU and one or more materials or components within, or on, the optical layer, that function as a UV and/or an IR reflector.

In other embodiments, the optical layer comprises a material selected from the group consisting of polyethylene terephthalate (PET), polycarbonate, polymethyl methacrylate (PMMA) and combinations thereof. In these embodiments, the interlayer may comprise a second TPU layer in contact with a first surface of the optical layer. The interlayer may further comprise a third TPU layer in contact with a second surface of the optical layer opposite the first surface. The second and third TPU layers provide adhesion of the optical layer to the first TPU layer and an outer layer of a laminate, such as a rigid glass or polymer sheet of a window.

In various embodiments, the optical layer comprises on or more materials or components that reflect at least some of the UV light passing through the optical layer, while substantially allowing visible light to pass therethrough. The UV reflectors preferably reflect light having wavelengths of about 100 nanometers to about 400 nanometers. Suitable UV reflectors for the optical layer include, but are not limited to, sheet polarizers, dichroic or reflective filter materials, e-PTFE films, aluminum sheets or foils, platinum, gold, rhodium, copper, silver and/or stainless steel films, and combinations thereof.

In various embodiments, the optical layer comprises on or more materials or components that reflect at least some of the IR light passing through the optical layer, while substantially allowing visible light to pass therethrough. The UV reflectors preferably reflect light having wavelengths of about 780 nanometers to about 1000 nanometers. Suitable IR reflectors include, but are not limited to, infrared reflecting films, mirrors, polarized films, non-polarized films, multi-layer films, colored or tinted films, metal, or metal-based coatings, double or triple layer silver coatings, or coatings or films comprising tin oxide, metal oxide, gold, aluminum, nitride, halide, sulfide, germanium, silicon, quartz, and combinations thereof.

In various embodiments, the interlayer is substantially optically transparent to visible light. The interlayer may have a Yellowness Index (YI) value of 3.0 or less, or 2.5 or less. The interlayer has a visible light transmission (VLT) of greater than about 50%, or greater than about 70%.

In various embodiments, the luminescent solar concentrators are quantum dots configured to capture light passing through the interlayer. The quantum dots may be coupled to one or more photovoltaic cells within the TPU layer that harvest the light captured from the quantum dots.

In various embodiments, the TPU layer has a quantum dot (QD) loading of less than about 1.0% or less than about 0.8%. The TPU layer has a capture efficiency of at least about 3%, or about 5%, or greater. Capture efficiency is defined herein as the percentage of total sun energy that passes through the layer that is captured by the layer.

In another aspect, a laminate is provided comprising the interlayer described above. The laminate comprises first and second substantially rigid sheets and the interlayer is disposed between the rigid sheets. The laminate may comprise, for example, a window unit for a vehicle or building. The first rigid sheet is an outwardly facing side of the window unit and the optical layer is disposed between the TPU layer and the second rigid sheet such that light from the exterior of the window is reflected from the optical layer back into the TPU layer.

In various embodiments, at least one of the first and second rigid sheets comprises glass. In other embodiments, at least one of the first and second rigid sheets comprises a polymer.

In another aspect, a laminate is provided comprising first and second rigid sheets and an interlayer disposed between the first and second rigid sheets. The interlayer comprises a thermoplastic polyurethane (TPU) layer comprising luminescent solar concentrators and an optical layer in contact with one of the first and second rigid sheets. The optical layer comprises one or more materials that reflect ultraviolet (UV) or infrared (IR) light back into the TPU layer.

In various embodiments, the first rigid sheet is an outwardly facing side of the laminate and the optical layer is disposed between the TPU layer and the second, or inwardly facing, rigid sheet. The optical layer is bonded to the second rigid sheet in any suitable manner, such as lamination, sputter deposition, vacuum deposition, spin coating, dip coating or the like.

In various embodiments, the optical layer comprises one or more materials or components that reflect at least some of the UV light passing through the optical layer, while substantially allowing visible light to pass therethrough. Suitable UV reflectors for optical layer include, but are not limited to, sheet polarizers, dichroic or reflective filter materials, e-PTFE films, aluminum sheets or foils, platinum, gold, rhodium, copper, silver and/or stainless steel films, and combinations thereof.

In various embodiments, the optical layer comprises on or more materials or components that reflect at least some of the IR light passing through the optical layer, while substantially allowing visible light to pass therethrough. Suitable IR reflectors include, but are not limited to, infrared reflecting films, mirrors, polarized films, non-polarized films, multi-layer films, colored or tinted films, metal, or metal-based coatings, double or triple layer silver coatings, tin oxide, metal oxide, gold, aluminum, nitride, halide, sulfide films, germanium, silicon, quartz, and combinations thereof.

In various embodiments, at least one of the first rigid sheet and second rigid sheet is a layer of glass. In some embodiments, at least one of the first rigid sheet and second rigid sheet is a layer of polymer.

In certain embodiments, the TPU layer and the optical layer can be wedge-shaped. Accordingly, the subcomponent may form part of a Head-Up-Display (HUD) window unit.

The window unit can further comprise electromagnetic shielding, a low emissivity layer, an electrochromic assembly, and/or a photovoltaic assembly.

It is to be understood that both the foregoing general description and the following detailed description are exemplary and explanatory only and are not restrictive of the disclosure. Additional features of the disclosure will be set forth in part in the description which follows or may be learned by practice of the disclosure.

### BRIEF DESCRIPTION OF THE DRAWINGS

The accompanying drawings, which are incorporated in and constitute a part of this specification, illustrate several embodiments and together with the description serve to explain certain principles.

FIG. 1 is cross-sectional view of an interlayer;

FIG. 2 is a cross-sectional view of a laminate; and

FIG. 3 is a cross-sectional view of another embodiment of a laminate.

### DETAILED DESCRIPTION

This description and the accompanying drawings illustrate exemplary embodiments and should not be taken as limiting, with the claims defining the scope of the present disclosure, including equivalents. Various mechanical, compositional, structural, and operational changes may be made without departing from the scope of this description and the claims, including equivalents. In some instances, well-known structures and techniques have not been shown or described in detail so as not to obscure the disclosure. Like numbers in two or more figures represent the same or similar elements. Furthermore, elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment. Moreover, the depictions herein are for illustrative purposes only and do not necessarily reflect the actual shape, size, or dimensions of the system or illustrated components.

It is noted that, as used in this specification and the appended claims, the singular forms “a,” “an,” and “the,” and any singular use of any word, include plural referents unless expressly and unequivocally limited to one referent. As used herein, the term “include” and its grammatical variants are intended to be non-limiting, such that recitation of items in a list is not to the exclusion of other like items that can be substituted or added to the listed items.

Described herein are interlayers having functional properties such as solar control properties and various structures including laminates with solar control interlayers. The laminated structures may be part of a window unit, for a vehicle or building or another structure, such as an image sensor, an electronic display screen for computers and mobile devices, a food packaging, an optical disk device, an appliance and the like. The solar control interlayers are designed to increase the efficiency of energy harvesting from sunlight without compromising other functional properties of the interlayer and the laminate, such as the visible light transmission (VLT).

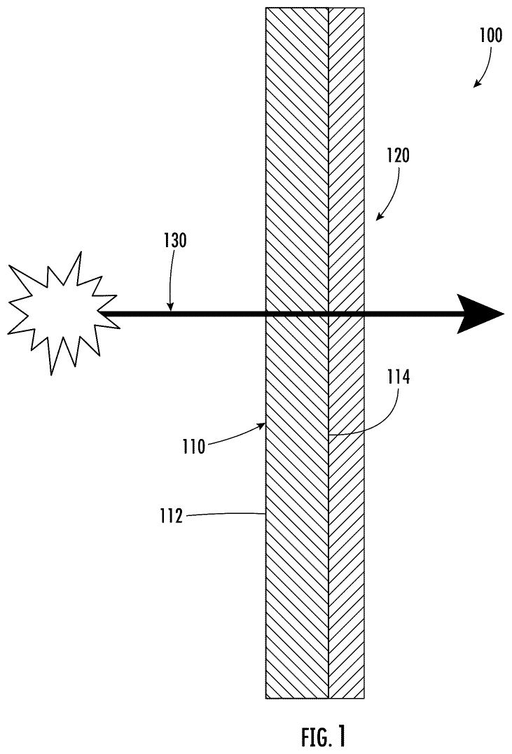

Referring now to FIG. 1, an interlayer 100 comprises a first polymer layer 110 and a second optical layer 120 in contact with one surface of the polymer layer 110. Polymer layer 110 comprises luminescent solar concentrators (LSCs), which may be, in some embodiments, colloidal semiconductor nanocrystals, also called quantum dots. A quantum dot is a nanoscale particle that exhibits size dependent electronic and optical properties due to quantum confinement. The quantum dots are typically less than 50 nanometers in diameter, preferably less than 20 nanometers, and are generally not visible. Natural light excites electrons of the quantum dot which guides the light to the sides of the layer. For example, the light may be guided to the long sides of the layer. Polymer layer further includes photovoltaic cells (not shown) that are in intimate contact with the sides of layer 110 to convert the light to electrical energy.

Some of the quantum dots may be made from a binary semiconductor material having a formula MX, where M is a metal and X typically is selected from sulfur, selenium, tellurium, nitrogen, phosphorus, arsenic, antimony, or mixtures thereof. Embodiments of the disclosed quantum dots may be of a single material, or may comprise an inner core and an outer shell (e. g., a thin outer shell/layer formed by any suitable method, such as cation exchange). The quantum dots may further include a plurality of ligands bound to the quantum dot surface.

In some embodiments, other luminescent solar concentrators may be used. Another suitable alternative to quantum dots for energy generation is organic photovoltaic (OPV) cells, which may be employed here. Organic photovoltaic cells may be applied using thin-film deposition such as by sputtering and pulsed-laser deposition to create this thin-film OPV for energy generation.

Polymer layer 110 has an outwardly facing side 112 and an inwardly facing side 114 and optical layer 120 is in contact with inwardly facing side 114 of polymer layer 110. Optical layer 120 comprises one or more materials that reflect light 130 that has already passed through TPU layer 110 back into TPU layer 110. Reflecting the solar energy back into the TPU layer allows the luminescent solar concentrators to harvest more energy from the same light rays, thereby increasing the efficiency of the luminescent solar concentrators without compromising other performance features of the interlayer (discussed below).

Optical layer 120 may be configured to reflect ultraviolet (UV) light, infrared (IR) light, visible light or light having other wavelengths (e.g., microwaves or radio waves). In an exemplary embodiment, optical layer 120 reflects UV and/or IR light.

In various embodiments, the interlayer is substantially optically transparent to visible light. The interlayer may have a Yellowness Index (YI) value of 3.0 or less or 2.5 or less or 1.5 or less. The interlayer has a visible light transmission (VLT) of greater than about 50%, or greater than about 60\hat{ } or greater than about 70%.

In various embodiments, the TPU layer has a quantum dot (QD) loading of less than about 1.0% or less than about 0.8%. The lower QD loading allows for higher VLT. The TPU layer has a capture efficiency of at least about 3%, or about 5%, or greater because the quantum dots harvest energy from light reflecting therethrough and then harvest energy from the IR and/or UV light that is reflected back into the TPU layer by optical layer 120. Thus, each quantum dot is able to capture energy twice from at least some of the light passing through the interlayer. Capture efficiency is defined herein as the percentage of total sun energy that passes through the layer that is captured by the layer.

In certain embodiments, optical layer 120 comprises TPU or a similar material that provides good adhesion to polymer layer 110 and/or other sheets in a laminate. Optical layer 120 may comprise a substantially transparent thermoplastic polyurethane (TPU) layer formed by extrusion and suitable for use in a laminate, such as a window unit. The thermoplastic polyurethane will preferably comprise a material that provides sufficient transparency to visible light and exhibits suitable adhesion to glass, polycarbonate, acrylic, cellulose acetate butyrate, or other surfaces which the layer may contact. The Yellowness Index (YI) value of optical layer 120 is preferably less than or equal to 3.0 and more preferably less than or equal to 2.5. Optical layer 120 preferably has a thickness of about 25 to about 400 microns, more preferably about 50 to about 150 microns.

In one embodiment, one or more materials or components are disposed within, or on, optical layer 120 that reflect UV light having a wavelength between about 100 nanometers and 400 nanometers. The optical material is preferably capable of reflecting at least about 10%, or at least about 25% or at least about 50% of the UV light passing through optical layer 120 while substantially allowing visible light to pass therethrough.

Suitable UV reflectors for optical layer include, but are not limited to, sheet polarizers, dichroic or reflective filter materials, e-PTFE films, aluminum sheets or foils, platinum, gold, rhodium, copper, silver and/or stainless steel films, and combinations thereof. For example, blue or green tinted glass with greatly reduced transmission in the UV portion or blue or green tinted polymeric interlayers, coatings or layers of UV radiation reflecting paint or lacquer may be suitable for the optical material.

In certain embodiments, the optical material may include two or more different materials or components disposed within, or on, optical layer 120 that reflect UV light within different ranges or bands of wavelengths within the UV spectrum. For example, the optical layer may include one material or component that reflects UV light having wavelengths in a range of about 100 to 280 nanometers (the UVC band), another material or component that substantially reflects UV light having wavelengths in the range of about 280 to 315 nanometers (the UVB band) and/or another material or component that reflects UV light having wavelengths in the range of about 315 to about 400 nm (the UVA band). Other similar configurations can be envisioned by those skilled in the art.

In another embodiment, or more materials or components are disposed within, or on, optical layer 120 that reflect IR light having a wavelength of about 700 nanometers to 1400 nm, or about 780 nm to about 1000 nm. The optical material is preferably capable of reflecting at least about 10%, or at least about 25% or at least about 50% of the IR light passing through optical layer 120 while substantially allowing the transmission of visible light therethrough.

Suitable IR reflectors include, but are not limited to, infrared reflecting films, mirrors, polarized films, non-polarized films, multi-layer films, colored or tinted films, metal, or metal-based coatings, double or triple layer silver coatings, tin oxide, metal oxide, gold, aluminum, nitride, halide, sulfide films, germanium, silicon, quartz, and combinations thereof.

In certain embodiments, optical layer 120 can be a metal or metal-based coating of the type that reflects IR wavelength light while transmitting visible light. The coating can be sputtered or otherwise applied to the inwardly facing surface 114 of TPU layer 110.

In some embodiments, transparent metal layers or a series of metal and dielectric layers can be applied by sputter deposition, vacuum deposition, or other processes. For example, layers of silver or silver gold alloy can be applied. In some embodiments, the dielectric material can be zirconium oxide, tantalum oxide, tungsten oxide, indium tin oxide, etc.

In certain embodiments, IR reflective coatings include double-layer silver coatings. In other embodiments, IR reflective coatings include triple-layer silver coatings. In yet other embodiments, the IR reflective coating be a triple-layer silver coating that also reflects light in the UV spectrum. Such double-layer silver coatings, triple-layer silver coatings and triple-layer silver coatings with enhanced IR and UV reflection are commercially available from PGW. Other reflecting type infrared filters includes a transparent medium such as glass, acrylic (PMMA) and quartz, stainless steel or tin oxide, metal oxide, nitride, halide, or sulfide films.

In another embodiment, optical layer 120 comprises an IR reflecting filter, such as blue glass, interlayer films comprising infrared-shielding fine particles, fluorophosphate-based infrared filter glass or phosphate-based infrared filter glass and the like.

In some embodiments, low-e layers may be employed, and such layers can include a sputter deposited silver layer between dielectric layers such as titanium oxide. In some embodiments, silica or a silica-based material can be applied in a sol-gel process. In some embodiments, an interlayer subcomponent, or a laminate for a window unit, can include a low-e layer.

In certain embodiments, optical layer 120 may include liquid crystal materials that selectively operate to transmit or scatter IR light.

Optical layer 120 may comprise two or more different layers, coatings, films, or other materials within each layer configured to reflect IR light in different wavelengths within the IR spectrum. For example, optical layer 120 may comprise a first IR layer or material that substantially reflects IR light having wavelengths in a range of about 700 to about 900 nanometers, a second IR layer or material that substantially reflects wavelengths in the range of about 900 to about 1000 nanometers and/or a third IR layer or material that substantially reflects wavelengths in the range of about 1000 to 1400 nanometers. Other similar configurations can be envisioned by those skilled in the art.

Polymer layer 110 may be a substantially transparent thermoplastic polyurethane (TPU) layer formed by extrusion and suitable for use in a laminate for a window unit. The thermoplastic polyurethane will preferably comprise a material that provides sufficient transparency to visible light and exhibits suitable adhesion to glass, polycarbonate, acrylic, cellulose acetate butyrate, or other surfaces which the films may contact. In preferred embodiments, the TPU material will exhibit abrasion resistance, heat resistance, and hardness to adverse weather elements for a long period of time. In addition, the material may have a storage modulus sufficient to substantially absorb and dissipate the kinetic energy of air particulates that contact its surface. The TPU layer(s) preferably has a thickness of about 100 to 800 microns, more preferably about 300 to 500 microns. In certain embodiments, the thermoplastic polyurethane is a material with high energy storage modulus properties and a relatively low durometer, preferably in the range of about 60-80 A, more preferably about 70-75 A.

The TPU preferably comprises an aliphatic thermoplastic polyurethane. Of course, it should be recognized by those skilled in the art that other polymer materials can be used with the present invention. For example, the polyurethane material may be a suitable aliphatic polyester or polycaprolactone. Alternatively, a thermoset polymer that is irreversibly hardened by curing from a soft solid or viscous liquid prepolymer may be used in combination with the thermoplastic polymer.

TPU layer 110 may comprise a TPU resin composition. In embodiments, suitable TPU resins may be polyether-based and made from methylene diphenyl diisocyanate (MDI), polyether polyol, and butanediol. In embodiments, the TPU resin may be Estane AG-8451 Resin sold by Lubrizol.

TPU layer 110 may also include other materials, such as UV radiation absorbing, blocking, or screening additives, stabilizers and the like. Suitable UV radiation absorbing, blocking, or screening additives include, but are not limited to, bezophenones, cinnamic acid derivatives, esters of benzoin acids, alicyclic acid, terephthalic and isophthalic acids with resorcinol and phenols, pentamethyl piperidine derivatives, salicylates, benzotriazoles, cyanoacrylates, benzylidenes, malonates and oxalamides. These additives may be combined with each other or with other materials, such as nickel chelates and hindered amines.

The UV absorber may be any suitable UV absorber made from compounds in the benzotriazole family. In other embodiments, the first UV absorber may be of the benzylidene malonate family. Non-limiting example of benzylidene malonate-type UV absorbers which may be used as the first UV absorber include: Propane dioic acid [(4-methoxyphenyl)-methylene]-dimethyl ester).

TPU layer 110 also include a light stabilizer. Suitable light stabilizers primarily protect the polymers of the optical film from the adverse effects of photo-oxidation caused by exposure to UV radiation. In embodiments, the light stabilizer may serve a secondary function of acting as a thermal stabilizer, for low to moderate levels of heat.

In certain embodiments, suitable light stabilizers may be derivatives of tetramethylpiperidine. In embodiments, the light stabilizer may be any suitable hindered amine light stabilizer (HALS or NOR-HALS). In certain embodiments, the light stabilizer may be made by combining bis(1, 2, 2, 6, 6-pentamethyl-4-piperidyl) sebacate with methyl 1, 2, 2, 6, 6-pentamethyl-4-piperidyl sebacate.

Non-limiting examples of light stabilizers useful in the resin compositions of the present disclosure include bis-(2,2,6,6-tetramethyl-4-piperidinyl) sebacate; bis-(1,2,2,6,6-pentamethyl-4-piperidinyl)-2-n-butyl-2-(3,5-di-tert-butyl-4-hydroxybenzyl) malonate; propanedioic acid, [(4-methoxyphenyl)-methylene]-bis-(1,2,2,6,6-pentamethyl-4-piperidinyl) ester; 10 wt. % of dimethyl succinate polymer with 4-hydroxy-2,2,6,6,-tetramethyl-1-piperidineethanol and 90 wt. % of N,N′″-[1,2-ethanediylbis[[[4,6-bis[butyl(1,2,2,6,6-pentamethyl-4-piperidinyl)-amino]-1,3,5-triazin-2-yl]imino]-3,1-propanediyl]] bis[N′N″-dibutyl-N′N″-bis(1, 2,2,6,6-pentamethyl-4-piperidinyl)]-1; or combinations thereof. In embodiments, the light stabilizer is bis(1,2,2,6,6-pentamethyl-4-piperidyl) sebacate combined with methyl 1,2,2,6,6-pentamethyl-4-piperidyl sebacate Chisorb 292 sold by Double Bond Chemical Ind. Co., Ltd., Eversorb 93, sold by Everlight Chemical, RIASORB UV-292 sold by Rianion Corp, Thasorb UV-292 sold by Rianlon Corp., Sabostab UV 65, sold by SABO, Westco UV-292 sold by Western Reserve Chemical, UV-292/UV-292HP sold by Performance Solutions, Inc., and FENTASTAB 292 sold by Jiangsu Forpi Chemicals Co., Ltd or any combination thereof.

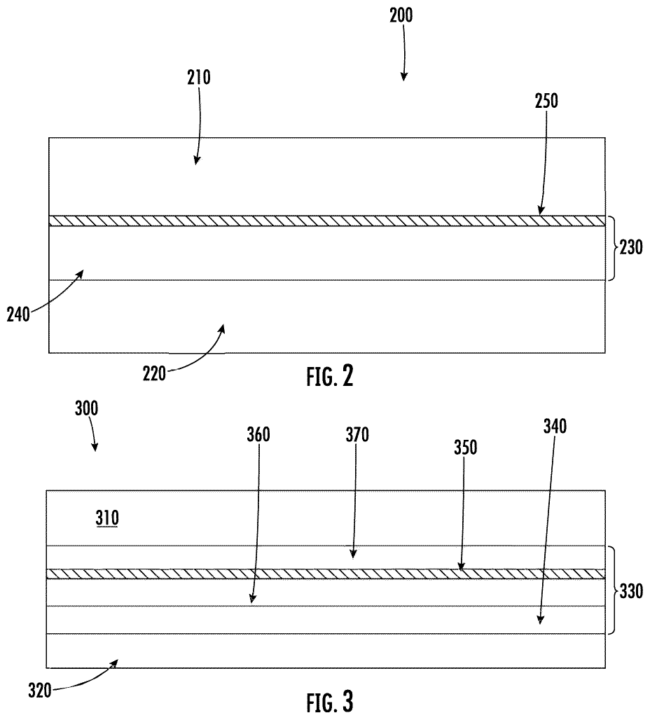

Referring now to FIG. 2, a laminate 200 comprises a first rigid sheet 210, a second rigid sheet 220 and an interlayer 230 disposed therebetween. Interlayer 230 comprises a TPU layer 240 and an optical layer 250. TPU layer 240 is disposed between optical layer 250 and second rigid sheet 220. The rigid sheets 210, 220 may comprise layers of glass, or optically clear rigid polymeric sheets such as, for example, polycarbonate, in an autoclave to form a window unit. Other rigid polymeric materials can be used, such as for example, acrylics, polyacrylate, polymethyl methacrylate, cellulose acetate, etc. In some embodiments, combinations of glass and polymeric sheets can be used. It is contemplated that non-autoclave processes may also be employed.

In some embodiments, the rigid outer layers, or substrates 210, 220 may be substantially transparent, abrasion resistant, and/or chemically inert substrates such as soda lime glass, chemically or thermally tempered glass or coated glass products with solar control features such as SUNGATET™ windshields from PPG Industries, Inc. and SOLARSHIELD™ glass from AFG Industries, Inc.

As described above, TPU layer 240 includes one or more LSCs that harvest energy from sunlight passing through second rigid sheet 220. Optical layer 250 reflects a certain portion of the light passing through TPU layer 240 back into TPU layer 240 to allow the luminescent solar concentrators to harvest more energy from the same light rays, thereby increasing the efficiency of the luminescent solar concentrators without compromising other performance features of the interlayer.

The interlayer subcomponent may be provided in a window frame. In certain embodiments, the window unit can be used on a specific side of a building, and can include transparent portions and semi-transparent or opaque portions. For example, transparent portions can include energy harvesting aspects, such as quantum dots that are disposed within the transparent portions, with photovoltaic cells disposed in portions that are not relied on for transparency, such as an opaque portion that does not form part of the window area. In other embodiments, photovoltaic cells can be located at one or more edges of the laminate or window unit.

In certain embodiments, the TPU layer 240 and the optical layer 250 can be wedge-shaped. Accordingly, the subcomponent may form part of a Head-Up-Display (HUD) window unit.

In an alternative embodiment, optical layer 250 is bonded to rigid sheet 210 such that optical layer 250 is disposed between rigid sheet 210 and TPU layer 240. Optical layer 250 may be laminated to sheet 210, or it may be spin coated, dip coated, sputtered, vacuum deposited or applied to sheet 210 in any other manner known by those skilled in the art. Optical layer 250 may comprise any suitable substrate material, such as TPU, polyethylene terephthalate (PET), polycarbonate, polymethyl methacrylate (PMMA) and combinations thereof. Optical layer may comprise one or more materials or components within, or on, the substrate material that are dyed, pigmented, and/or metallized.

The materials within optical layer 250 may comprise an IR reflector, such as infrared reflecting films, mirrors, polarized films, non-polarized films, multi-layer films, colored or tinted films, metal, or metal-based coatings, double or triple layer silver coatings, tin oxide, metal oxide, gold, aluminum, nitride, halide, sulfide films, germanium, silicon, quartz, and combinations thereof. The materials may comprise a UV reflector such as polarizers, dichroic or reflective filter materials, e-PTFE films, aluminum sheets or foils, platinum, gold, rhodium, copper, silver and/or stainless steel films, and combinations thereof. The material may comprise ceramic or copper. The materials may comprise nanoparticles.

Referring now to FIG. 3, a laminate 300 comprises a first rigid sheet 310, a second rigid sheet 320 and an interlayer 330 disposed therebetween. Interlayer 330 comprises a first TPU layer 340 and an optical layer 350. In this embodiment, optical layer 350 comprises a material selected from the group consisting of polyethylene terephthalate (PET), polycarbonate, polymethyl methacrylate (PMMA) and combinations thereof. Optical layer 350 may comprise a material that does not provide the same degree of adhesion as TPU. Accordingly, interlayer 330 further comprises a second TPU layer 360 in contact with a first surface of optical layer 350 and a third TPU layer 370 in contact with a second surface of optical layer 350 opposite the first surface. The second and third TPU layers 360, 370 provide adhesion of optical layer 350 to first TPU layer 340 and rigid sheet 310.

Other layers can be added to provide desired functional properties, such as for example, electrochromic features, impact resistance, sound dampening, structural strength, and electromagnetic shielding, etc. These layers can be any of the materials mentioned herein, rigid optically clear polymeric sheets, or combinations thereof.

In some embodiments, the interlayer can include electromagnetic shielding and/or conductive properties such as nanowires, sputtered electrodes, etc., that are not visible. Low emissivity layers, transparent conductive films, carbon nanotube transparent electrodes, and other features can be included as part of the interlayer subcomponent. The interlayer subcomponent can include photovoltaic assemblies, electrochromic assemblies, acoustic dampening layers, impact resisting layers, etc. In certain embodiments, one or more such functional layers are provided as the interlayer subcomponent, with polymeric layers on each of two opposing sides of the interlayer subcomponent having adhesive properties when heated.

The interlayer can include electromagnetic interference (EMI) shielding, to protect a wireless network or other system in a vehicle or building from electromagnetic interference. EMI shielding layers can include several layers of metal that allow substantial transmission of visible light and may be provided on a polymer substrate such as PET or PEN. For example, alternating layers of dielectric or metal oxide and metal can be formed as a stack and combined with other layers in an interlayer subcomponent or provided in a laminate. The dielectric or metal oxide can include, for example, In₂ O₃, Ti O₂, Nb₂ O₅, Ta₂ O₅, Sn O₂, Zn O or indium tin oxide (ITO). The metal can be, for example, silver, gold, copper, aluminum. In some embodiments, the subcomponent can include a stack of layers of ITO and silver applied by sputter deposition or vapor deposition.

A hard coat may be combined with the interlayer subcomponent disclosed herein. For example, a hard coat can be formed from epoxy, resin, etc. For example, the hard coat can be a cured layer of resin such as, for example, curable particles of silica. For example, UV cured materials may be used.

In certain embodiments, TPU layer can be a multilayer stack having electrochromic properties. Electrochromic assemblies can include an electrochromic material having a transparent electrode formed on each opposing side. The electrochromic material is sensitive to an applied voltage. For example, transitional metal oxides are used in the electrochromic material. In some embodiments, transparent conductive layers can be disposed on a layer having a tungsten oxide (“WO3”) electrochromic material deposited on a PET substrate. Such electrochromic materials can be deposited by sputtering, chemical vapor deposition, and other methods. The electrochromic solar control layer or film functions by adjusting the total light transmission in the visible and infrared range. In this example, it is a variable transmission solar control film.

Other embodiments will be apparent to those skilled in the art from consideration of the specification and practice of the embodiment disclosed herein. It is intended that the specification and examples be considered as exemplary only, with a true scope and spirit of the embodiment being indicated by the following claims.

For example, according to one aspect, in a 1^{st} embodiment, an interlayer comprises a thermoplastic polyurethane (TPU) layer comprising luminescent solar concentrators and an optical layer in contact with the TPU layer. The optical layer comprising one or more materials that reflect light into the TPU layer.

A second embodiment is the first embodiment, wherein the optical layer reflects ultraviolet (UV) light or infrared (IR) light into the TPU layer.

A 3^{rd} embodiment is any combination of the first 2 embodiments, wherein the optical layer comprises TPU.

A 4^{th} embodiment is any combination of the first 3 embodiments, wherein the optical layer comprises a material selected from the group consisting of polyethylene terephthalate (PET), polycarbonate, polymethyl methacrylate (PMMA) and combinations thereof.

A 5^{th} embodiment is any combination of the first 4 embodiments, further comprising a second TPU layer in contact with a first surface of the optical layer.

A 6^{th} embodiment is any combination of the first 5 embodiments, further comprising a third TPU layer in contact with a second surface of the optical layer opposite the first surface.

A 7^{th} embodiment is any combination of the first 6 embodiments, wherein the optical layer comprises a UV reflector.

An 8^{th} embodiment is any combination of the first 7 embodiments, wherein the UV reflector is selected from a group consisting of polarizers, dichroic or reflective filter materials, e-PTFE films, aluminum sheets or foils, platinum, gold, rhodium, copper, silver and/or stainless steel films, and combinations thereof.

A 9^{th} embodiment is any combination of the first 8 embodiments, wherein the optical layer comprises an IR reflector.

A 10^{th} embodiment is any combination of the first 9 embodiments, wherein the IR reflector is selected from a group consisting of infrared reflecting films, mirrors, polarized films, non-polarized films, multi-layer films, colored or tinted films, metal, or metal-based coatings, double or triple layer silver coatings, or coatings or films comprising tin oxide, metal oxide, gold, aluminum, nitride, halide, sulfide, germanium, silicon, quartz, and combinations thereof.

An 11^{th} embodiment is any combination of the first 10 embodiments, wherein the optical layer is substantially optically transparent to visible light.

A 12^{th} embodiment is any combination of the first 11 embodiments, wherein the optical layer has a Yellowness Index (YI) value of 3.0 or less.

A 13^{th} embodiment is any combination of the first 12 embodiments, wherein the luminescent solar concentrators are quantum dots.

A 14^{th} embodiment is any combination of the first 13 embodiments, wherein the TPU layer further comprises one or more photovoltaic cells coupled to the luminescent solar concentrators.

A 15^{th} embodiment is any combination of the first 14 embodiments, wherein the TPU layer has a quantum dot loading of less than about 1.0%.

A 16^{th} embodiment is any combination of the first 15 embodiments, wherein the quantum dot loading is about 0.8%.

A 17^{th} embodiment is any combination of the first 16 embodiments, wherein the TPU layer has a capture efficiency value of at least about 3%.

An 18^{th} embodiment is any combination of the first 17 embodiments, wherein the capture efficiency is at least about 5%.

A 19^{th} embodiment is any combination of the first 18 embodiments, wherein the interlayer has a visible light transmission (VLT) of greater than about 50%.

A 20^{th} embodiment is any combination of the first 19 embodiments, wherein the VLT is greater than about 70%.

A 21^{st} embodiment is any combination of the first 20 embodiments, wherein the luminescent solar concentrators comprise an electrochromic assembly.

A 22^{nd} embodiment is any combination of the first 21 embodiments, wherein the electrochromic assembly includes transparent electrodes.

In another aspect, a laminate is provided comprising the interlayer of any combination of the above 22 embodiments, the laminate further comprised first and second rigid sheets, wherein the interlayer is disposed between the first and second rigid sheets.

In another aspect, a window unit for a vehicle or building comprising the laminate of any combination of the above 23 embodiments.

A second embodiment is the first embodiment, wherein, at least one of the first rigid sheet and the second rigid sheet comprises glass.

A third embodiment is any combination of the first 2 embodiments, wherein at least one of the first rigid sheet and the second rigid sheet comprises a polymer.

A 4^{th} embodiment is any combination of the first 3 embodiments, wherein the first rigid sheet is an outwardly facing side of the window unit and the optical layer is disposed between the TPU layer and the second rigid sheet.

In another aspect, a first embodiment is a laminate comprising first and second substantially rigid sheets and an interlayer disposed between the first and second rigid sheets. The interlayer comprises a thermoplastic polyurethane (TPU) layer and luminescent solar concentrators within the TPU layer and an optical layer in contact with the TPU layer. The optical layer comprises one or more materials that reflect ultraviolet (UV) or infrared (IR) light into the TPU layer.

A second embodiment is the first embodiment, wherein the first rigid sheet is an outwardly facing side of the laminate and the optical layer is disposed between the TPU layer and the second rigid sheet.

A third embodiment is any combination of the first 2 embodiments, wherein the optical layer is bonded to the TPU layer.

A 4^{th} embodiment is any combination of the first 3 embodiments, wherein the optical layer comprises TPU.

A 5^{th} embodiment is any combination of the first 4 embodiments, wherein the optical layer comprises a UV reflector.

A 6^{th} embodiment is any combination of the first 5 embodiments, wherein the optical layer comprises an IR reflector.

A 7^{th} embodiment is any combination of the first 6 embodiments, wherein the optical layer is substantially optically transparent to visible light.

An 8^{th} embodiment is any combination of the first 7 embodiments, wherein the optical layer has a Yellowness Index (YI) value of 3.0 or less.

A 9^{th} embodiment is any combination of the first 8 embodiments, wherein the luminescent solar concentrators are quantum dots.

A 10^{th} embodiment is any combination of the first 9 embodiments, wherein the TPU layer further comprises one or more photovoltaic cells coupled to the luminescent solar concentrators.

An 11^{th} embodiment is any combination of the first 10 embodiments, wherein the TPU layer has a quantum dot loading of less than about 1.0%.

A 12^{th} embodiment is any combination of the first 11 embodiments, wherein the quantum dot loading is about 0.8%.

A 13^{th} embodiment is any combination of the first 12 embodiments, wherein the laminate has a visible light transmission (VLT) of greater than about 50%.

A 14^{th} embodiment is any combination of the first 13 embodiments, wherein the VLT is greater than about 70%.

In another aspect, a window unit for a vehicle or building is provided comprising any combination of the above 14 embodiments.

A second embodiment is the first embodiment, wherein at least one of the first rigid sheet and the second rigid sheet comprises glass.

A third embodiment is any combination of the first 2 embodiments, wherein at least one of the first rigid sheet and the second rigid sheet comprises a polymer.

What is claimed is:

1. An interlayer comprising:
a thermoplastic polyurethane (TPU) layer comprising luminescent solar concentrators; and
an optical layer in contact with the TPU layer, the optical layer comprising one or more materials that reflect light into the TPU layer.

2. The interlayer of claim 1, wherein the optical layer reflects ultraviolet (UV) light or infrared (IR) light into the TPU layer.

3. The interlayer of claim 1, wherein the optical layer comprises TPU.

4. The interlayer of claim 1, wherein the optical layer comprises a material selected from the group consisting of polyethylene terephthalate (PET), polycarbonate, polymethyl methacrylate (PMMA) and combinations thereof.

5. The interlayer of claim 4, further comprising a second TPU layer in contact with a first surface of the optical layer.

6. The interlayer of claim 5, further comprising a third TPU layer in contact with a second surface of the optical layer opposite the first surface.

7. The interlayer of claim 1, wherein the optical layer comprises a UV reflector.

8. The interlayer of claim 7, wherein the UV reflector is selected from a group consisting of polarizers, dichroic or reflective filter materials, e-PTFE films, aluminum sheets or foils, platinum, gold, rhodium, copper, silver and/or stainless steel films, and combinations thereof.

9. The interlayer of claim 1, wherein the optical layer comprises an IR reflector.

10. The interlayer of claim 8, wherein the IR reflector is selected from a group consisting of infrared reflecting films, mirrors, polarized films, non-polarized films, multi-layer films, colored or tinted films, metal, or metal-based coatings, double or triple layer silver coatings, or coatings or films comprising tin oxide, metal oxide, gold, aluminum, nitride, halide, sulfide, germanium, silicon, quartz, and combinations thereof.

11. The interlayer of claim 1, wherein the luminescent solar concentrators are quantum dots.

12. The interlayer of claim 11, wherein the TPU layer has a quantum dot loading of less than about 1.0%.

13. The interlayer of claim 11, wherein the TPU layer has a capture efficiency of at least about 3%.

14. A laminate comprising:
first and second substantially rigid sheets; and
an interlayer disposed between the first and second rigid sheets, wherein the interlayer comprises:
a thermoplastic polyurethane (TPU) layer and luminescent solar concentrators within the TPU layer; and
an optical layer in contact with the TPU layer, the optical layer comprising one or more materials or components that reflect light into the TPU layer.

15. The laminate of claim 14, the optical layer reflects ultraviolet (UV) or infrared (IR) light into the TPU layer.

16. The laminate of claim 14, wherein the first rigid sheet is an outwardly facing side of the laminate and the optical layer is disposed between the TPU layer and the second rigid sheet.

17. The laminate of claim 14, wherein the optical layer is bonded to the TPU layer.

18. The laminate of claim 14, wherein the optical layer comprises TPU.

19. The laminate of claim 14, wherein the optical layer comprises a UV reflector.

20. The laminate of claim 14, wherein the optical layer comprises an IR reflector.
